(19) United States
(12) Patent Application Publication
(10) Pub. No.: US 2005/0247995 A1
(43) Pub. Date: Nov. 10, 2005

(54) Metal contact fuse element

(76) Inventors: Robert L. Pitts, Dallas, TX (US); Bryan Sheffield, Rowlett, TX (US); Roger Greismer, Murphy, TX (US)

Correspondence Address: TEXAS INSTRUMENTS INCORPORATED, P O BOX 655474, M/S 3999, DALLAS, TX, 75265, US

(21) Appl. No.: 10/840,444

(22) Filed: May 6, 2004

(51) Int. Cl. H01L 21/82; H01L 29/00; H01L 21/44

(52) U.S. Cl. 257/529; 438/132

(57) ABSTRACT

Severable metal contacts (42) are provided for use within a circuit in a semiconductor device whereby an open circuit may be formed by the application of a pre-selected voltage or current. Preferred embodiments and associated methods are described in which a semiconductor device fuse (30) includes first and second conductors (36, 38) having first and second metallic contacts (40, 42) operably coupled to a conductive layer (34) for forming an electrical path. At least one of the metallic contacts (42) is configured to operate as a metallic fuse element adapted to form an open circuit (44) in response to reaching a pre-selected voltage threshold or current. Preferred embodiments of the invention are described in which it is used for programmable read only memory (PROM) elements.

### TECHNICAL FIELD

The invention relates to semiconductor devices and integrated circuits (ICs). More particularly, it relates to new metallic contact fuse elements for use in IC devices and methods for assembling the same.

### BACKGROUND OF THE INVENTION

Fuse elements have been known almost as long as electrical equipment. Fuses were first used to protect electrical equipment from excessive voltage. More recently, fuses have also been used to implement programmable read-only memory (PROM) devices. Although fuses have evolved considerably from their distant ancestors, the operating principle has remained the same; an electrical element is destroyed when subjected to excessive current, creating an open circuit. In order to “blow” or “program” a fuse, a certain amount of current must be applied to the fuse element. The voltage required for injecting this amount of current must obviously be within the capacity of the available power supply. Under constant stress from high voltage for a sufficient time, the element heats enough to cause the element material to agglomerate or melt, ultimately causing a gap to form in the material, greatly increasing the element's resistance. As a result, the current through the element then decreases to a relatively low value and the element cools down. Once the fuse element is programmed, additional voltage stress will not significantly change its post-programming resistance.

It is known in the current state of the electronic arts to use fuse elements as a means to implement programmable logic states which can be used as control elements in a circuit. These control elements are used to capture device identification codes, program redundancy in memory arrays, for analog trimming, or for a host of other programmable uses. The control element is a type of programmable read-only memory (PROM).

A representative example of a “bow tie” poly fuse 10 familiar in the arts is shown in a top view in FIG. 1, and in the cross-section views of FIGS. 2A and 2B, taken along line 2-2 of FIG. 1. First referring to FIG. 1 and FIG. 2A, a representative un-programmed fuse 10 is described. In semiconductor devices, it is generally known to construct fuses 10 having a poly-silicon layer 12, typically with a conductive layer of titanium, cobalt, or other type of silicide 14 on top. The fuse element “bow tie” 16 shape shown is typical, and is positioned between a first conductor 18 and a second conductor 20, each joined in turn to associated circuitry (not shown). The first and second conductors 18, 20, are electrically coupled to the fuse element 16 with one or more first and second metallic contacts 22, 24. The fuse 10 is programmed by the application of current sufficient to heat the silicide 14 to a temperature high enough to cause damage disrupting the continuity of the silicide 14 and/or poly-silicon 12 layers. This creates an open circuit.

FIG. 2B illustrates an example of a fuse 10 as shown in FIG. 2A having an open circuit 26 subsequent to programming. The silicide 14 and/or poly-silicon 12 layers have a gap 26 induced by the heating of the silicide 14 and/or poly-silicon 12 due to the application of sufficient voltage between the first and second conductors 18, 20. It should be understood that the configuration of the fuse 10 ensures that the gap 26 is formed on the relatively thin (e.g. 0.20-0.30 um in a fuse about 2.0 um in length) bow tie 16 element. Of course, those skilled in the arts will recognize that the example shown and described with reference to FIGS. 1 through 2B is merely a representative example of poly-silicon fuses illustrating the principles of their operation in general, and is not intended to be limited to the particulars shown and described.

The initial resistance of the fuse element to current damage is highly dependent upon the geometry of the element and upon the thickness and quality of the silicide and poly-silicon. Silicide and poly-silicon quality is in turn dependent on process conditions and element geometry. For example, longer elements are more likely to have silicide imperfections. Additionally, the properties of the silicide can be affected by the doping level and type of the underlying poly-silicon. Thus, problems exist in the art due to the physical and electrical properties inherent in the silicide and in variations in the siliciding process.

Variations in the post-programming resistance of “blown” poly fuses can also present problems. Post-programming resistance depends largely on the size and shape of the discontinuity in the silicide layer. Fuse element shape, programming voltage, current, and time, as well as initial fuse integrity can all significantly affect the shape of the gap in the blown poly fuse. The inconsistencies in gap size and abruptness cause variations in the resistance of programmed fuses. These variations can cause problems with detecting the state of the fuses, i.e.; programmed/un-programmed, and must be compensated for when using the device.

Due to these and other problems, yields in programmed devices can suffer from inconsistencies inherent in the poly fuse elements caused by relatively subtle variations in processes and materials. In efforts to increase yield, higher voltages are sometimes applied in order to ensure the programming of fuses, which may risk undesirable effects on other portions of a device. As a result of the constraints of poly fuses, the optimum yield point in terms of voltage and pulse width is often very narrow and small process changes can frequently require re-optimization, resulting in increased manufacturing costs. Improved fuses addressing these and other problems and providing increased consistency and methods for providing higher yields would be useful and advantageous in the arts.

### SUMMARY OF THE INVENTION

In carrying out the principles of the present invention, in accordance with preferred embodiments thereof, severable metal contacts are provided within a circuit in a semiconductor device whereby an open circuit may be formed by the application of a selected voltage.

According to one aspect of the invention, a semiconductor device fuse includes first and second conductors having first and second metallic contacts operably coupled to a conductive layer for forming an electrical path. At least one of the metallic contacts is configured to operate as a metallic fuse element adapted to form an open circuit in response to reaching a pre-selected voltage threshold.

According to an additional aspect of the invention, a semiconductor device contact for providing a severable conductive path between a first conductor and a second conductor includes a first metallic contact electrically connecting the first conductor with a conductive layer. A second metallic contact for electrically connecting the second conductor with the conductive layer is also provided. At least one of the metallic contacts is adapted to form an open circuit in response to reaching a pre-selected voltage threshold.

According to a further aspect of the invention, a method of forming a programmable read-only memory (PROM) element is disclosed in which a first conductor having a first metallic contact is formed and a conductive layer is operably coupled to the first metallic contact. A second conductor having a second metallic contact is also formed and coupled to the conductive layer. An electrical path is thus provided from the first conductor through the first metallic contact, through the conductive layer, through the second metallic contact, and through the second conductor. According to the methods of the invention, one of the metallic contacts is adapted to function as a metallic fuse element for forming an open circuit in response to reaching a selected voltage threshold.

Preferred embodiments of the invention are disclosed wherein metal semiconductor contacts adapted to be used as fuse elements include tungsten.

The invention provides technical advantages including but not limited to favorable programming yield, lower programming voltage levels, increased blow algorithm margins, and decreased costs. These and other features, advantages, and benefits of the present invention can be understood by one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 (prior art) is a top view of an example of a prior art fuse structure using a poly-silicon fuse element;

FIG. 2A (prior art) is a sectional side view of an example of a prior art fuse structure in an un-programmed state taken along line 2-2 of FIG. 1;

FIG. 2B (prior art) is a sectional side view of an example of a prior art fuse structure in a programmed state taken along line 2-2 of FIG. 1;

FIG. 3 is a top view of an example of a fuse structure according to an example of a preferred embodiment of the invention;

FIG. 4A is a sectional side view of an example of a fuse structure in an un-programmed state taken along line 4-4 of FIG. 3; and

FIG. 4B is a sectional side view of an example of a fuse structure in a programmed state taken along line 4-4 of FIG. 3.

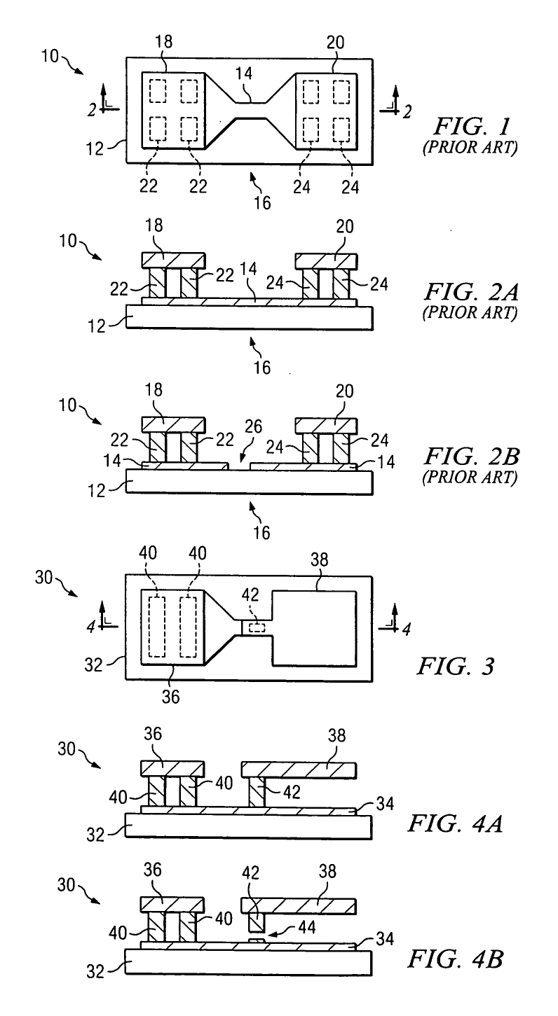

References in the detailed description correspond to the references in the figures unless otherwise noted. Descriptive and directional terms used in the written description such as first, second, top, bottom, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general the invention provides an improved semiconductor device fuse element for use in providing programmed logic arrays. The fuse element of the invention uses a metal contact in the formation of an open circuit for a “blown” fuse.

Referring now to FIG. 3 and FIGS. 4A, and 4B, an example of an improved semiconductor device fuse 30 according to a preferred embodiment of the invention is shown. A base layer 32 is provided with a conductive layer 34 for transmitting electric current. The base layer 32 may be silicon, poly-silicon, or other semiconductor material and the conductive layer 34 may be silicided poly or metallic material as long as a conductive electrical path is provided. It should be appreciated by those skilled in the arts that the figures shown and described illustrate a relatively small portion of a larger semiconductor, which includes a good deal of associated circuitry not shown. The essentials of the invention may be understood in the context of a conductive path between elements in a more complex circuit. Of course, the complex circuit may be comprised of numerous additional components including multiple fuses constructed according to the invention. A first conductor 36 is shown coupled to a second conductor 38 as further described. The first and second conductors 36, 38, are preferably electrically connected to associated circuitry not shown. It is assumed for the purposes of describing the examples of the invention herein that the associated circuitry is capable of supplying a voltage between the first and second conductors 36, 38. Preferably, one or more first metallic contacts 40, typically copper, although other metals or alloys may be used, electrically connect the first conductor 36 to the conductive layer 34.

Now referring primarily to FIG. 4A, a second metallic contact 42 couples the second conductor 38 with the conductive layer 34 as shown. It has been found that tungsten is suitable for use in forming the second metallic contact 42, but other metals or alloys may also be used without departure from the invention. It can be seen that an electrical path is provided from the first conductor 36 through the first metallic contact 40, in turn through the conductive layer 34, through the second metallic contact 42, and finally through the second conductor 38, and ultimately to a power supply (not shown). Those skilled in the arts will recognize that the elements shown and described may be formed using various suitable materials and processes. For example, the metallic contacts may be formed by patterning, etching and deposition techniques or by drilling and filling vias. Many alternative embodiments may be used within the confines of the invention. FIG. 4A illustrates an example of a fuse 30 according to the invention in an un-programmed state.

Understanding of the principles of the invention may be further enhanced by reference to FIG. 4B, depicting a fuse 30 according to the invention in a programmed state. As shown, the fuse 30 has a gap 44 in the second metallic contact 42. The gap 44 is formed by the application of a pre-selected programming voltage level between the first and second conductors 36, 38. The second metallic contact 42 is adapted to form the gap 44 in order to provide an open circuit resistant to the flow of electric current between the first and second conductors 36, 38. The second contact 42 is preferably configured for programming at a particular voltage threshold by adjusting its geometry and materials according to testing and simulations as known in the arts. Although tungsten is used to form a second contact 42 in the preferred embodiment shown due to its tendency to predictably form an abrupt gap 44, other metals and alloys may alternatively be used based on application requirements. Artisans will recognize that the first metallic 40 contact may, additionally or alternately, be configured for the formation of a fuse element. It should also be clear to those skilled in the arts that the contact fuse element of the invention may be used for circuit protection or for programmable logic circuits.

It has been found that fuses made according to the invention may be programmed with favorable yields at lower voltages than previously thought reliable in the arts. It is believed that the metal contact fuse element of the invention provides increased consistency and reliability by providing a fuse element with increased initial integrity, ensuring a more dramatic failure upon gap formation, providing a suitably wide gap with relatively abrupt edges. Additionally, it has been found that the fuse element of the invention is less susceptible to process variations than fuse elements known in the arts. Thus, the invention provides improved methods and apparatus for programmable memory cells and circuit protection in semiconductor electronics using a metal contact fuse element. The methods and devices of the invention provide advantages including but not limited to improved programming yield, lower programming voltage levels, broad blow algorithm margins, and decreased costs. While the invention has been described with reference to certain illustrative embodiments, the methods and apparatus described are not intended to be construed in a limited sense. Various modifications and combinations of the illustrative embodiments as well as other advantages and embodiments of the invention will be apparent to persons skilled in the art upon reference to the description and claims.

1. A semiconductor device fuse comprising:
a first conductor having a first metallic contact;
a conductive layer operably coupled to the first metallic contact;
a second conductor having a second metallic contact operably coupled to the conductive layer;
whereby an electrical path is provided from the first conductor through the first metallic contact, in turn through the conductive layer, through the second metallic contact, and finally through the second conductor; and
wherein at least one of the metallic contacts further comprises a metallic fuse element configured to form an open circuit in response to reaching a pre-selected voltage or current threshold.

2. A semiconductor device fuse according to claim 1 wherein the first metallic contact comprises a metallic fuse element configured to form an open circuit in response to reaching a pre-selected voltage or current threshold.

3. A semiconductor device fuse according to claim 1 wherein the second metallic contact comprises a metallic fuse element configured to form an open circuit in response to reaching a pre-selected voltage or current threshold.

4. A semiconductor device fuse according to claim 1 wherein at least one metallic contact comprises tungsten.

5. A semiconductor device fuse according to claim 1 wherein the pre-selected voltage threshold is less than approximately 3V.

6. A semiconductor device fuse according to claim 1 wherein the conductive layer comprises poly-silicon or active.

7. A semiconductor device contact for providing a severable conductive path between a first conductor and a second conductor comprising:
a first metallic contact electrically connecting the first conductor with a semiconductor element;
a second metallic contact electrically connecting the second conductor with the semiconductor element;
wherein one metallic contact is adapted to form an open circuit in response to reaching a pre-selected voltage or current threshold.

8. A semiconductor device contact according to claim 7 wherein the first metallic contact further comprises a metallic fuse element configured to form an open circuit in response to reaching a pre-selected voltage or current threshold.

9. A semiconductor device contact according to claim 7 wherein the second metallic contact further comprises a metallic fuse element configured to form an open circuit in response to reaching a pre-selected voltage or current threshold.

10. A semiconductor device contact according to claim 7 wherein at least one metallic contact comprises tungsten.

11. A semiconductor device contact according to claim 7 wherein the pre-selected voltage threshold is less than approximately 3V.

12. A semiconductor device contact according to claim 7 wherein the conductive layer comprises poly-silicon or active.

13. A method of forming a programmable read-only memory (PROM) element comprising the steps of:
forming a first conductor having a first metallic contact;
forming a conductive layer operably coupled to the first metallic contact;
forming a second conductor having a second metallic contact operably coupled to the conductive layer;
whereby an electrical path is provided from the first conductor through the first metallic contact, in turn through the conductive layer, through the second metallic contact, and finally through the second conductor; and
wherein at least one of the metallic contacts further comprises a metallic fuse element configured to form an open circuit in response to the application of a pre-selected voltage.

14. A method of forming a programmable read-only memory (PROM) element according to claim 13 further comprising the step of forming the first metallic contact in a configuration whereby an open circuit will form in response to the application of a pre-selected voltage or current.

15. A method of forming a programmable read-only memory (PROM) element according to claim 13 further comprising the step of forming the second metallic contact in a configuration whereby an open circuit will form in response to the application of a pre-selected voltage or current.

16. A method of forming a programmable read-only memory (PROM) element according to claim 13 further comprising the step of forming at least one metallic contact using tungsten.

17. A method of forming a programmable read-only memory (PROM) element according to claim 13 further comprising the step of selecting a voltage threshold of less than approximately 3V.

18. A method of forming a programmable read-only memory (PROM) element according to claim 13 further comprising the step of forming the conductive layer using poly-silicon or active.

19. A method of storing data in a programmable read-only memory (PROM) element comprising the steps of:
programming a severable metallic contact in a semiconductor circuit by the application of a pre-selected voltage or current level.

20. A method of storing data in a programmable read-only memory (PROM) element according to claim 19 further comprising the step of applying a voltage of less than approximately 3V.
